(19) United States
(12) Patent Application Publication
(10) Pub. No.: US 2026/0206425 A1
(43) Pub. Date: Jul. 16, 2026

(54) DISPLAY DEVICE AND MANUFACTURING METHOD OF THE SAME

(71) Applicant: Magnolia White Corporation, Tokyo (JP)

(72) Inventors: Tomokazu ISHIKAWA, Tokyo (JP); Tatsuya IDE, Tokyo (JP); Sho YANAGISAWA, Tokyo (JP); Hideyuki TAKAHASHI, Tokyo (JP)

(73) Assignee: Magnolia White Corporation, Tokyo (JP)

(21) Appl. No.: 19/426,161

(22) Filed: Dec. 19, 2025

(30) Foreign Application Priority Data
Jan. 14, 2025 (JP) 2025-004790

(51) Int. Cl. H10K 59/122; H10K 59/12; H10K 59/80

(52) U.S. Cl. CPC H10K 59/122; H10K 59/1201; H10K 59/873

(57) ABSTRACT

According to one embodiment, a display device includes a display panel including a display area, a terminal area, and a strip-shaped area located between the display area and the terminal area, the display panel being folded around an axis in the strip-shaped area. The display panel includes a first inorganic insulating layer not provided in the strip-shaped area, a first organic insulating layer provided on the first inorganic insulating layer, and provided in the strip-shaped area, a second organic insulating layer provided on the first organic insulating layer, and a plurality of first partitions provided above the second organic insulating layer. Each of the plurality of first partitions is formed in an overhang shape and extends along the axis.

### CROSS-REFERENCE TO RELATED APPLICATION

This application is based upon and claims the benefit of priority from Japanese Patent Application No. 2025-004790, filed Jan. 14, 2025, the entire contents of which are incorporated herein by reference.

### FIELD

Embodiments described herein relate generally to a display device and a manufacturing method of the same.

### BACKGROUND

Recently, display devices with organic light-emitting diodes (OLED) applied thereto as display elements have been put into practical use. Each of these display elements comprises a pixel circuit including a thin-film transistor, a lower electrode connected to the pixel circuit, an organic layer covering the lower electrode, and an upper electrode covering the organic layer.

Display devices comprising the display elements demand a technique for suppressing decreases in reliability.

### BRIEF DESCRIPTION OF THE DRAWINGS

FIG. 1 is a plan view showing a configuration example of a display device DSP.

FIG. 2 is a view showing a state in which a display panel PNL shown in FIG. 1 is folded.

FIG. 3 is a view showing an example of the layout of subpixels SP1, SP2, and SP3 in a display area DA.

FIG. 4 is a schematic cross-sectional view of the display device DSP along the A-B line of FIG. 3.

FIG. 5 is a plan view showing a shape of a partition 7 in a strip-shaped area BA1.

FIG. 6 is a plan view showing a shape of the partition 7 in a strip-shaped area BA2.

FIG. 7 is a schematic cross-sectional view of the display device DSP along the C-D line of FIG. 5.

FIG. 8A is a schematic cross-sectional view of the display device DSP along a connection line CN in the strip-shaped area BA1 shown in FIG. 5.

FIG. 8B is a schematic cross-sectional view of the display device DSP including a terminal area TA.

FIG. 9 is an enlarged cross-sectional view of the display panel PNL folded in the strip-shaped area BA1.

FIG. 10 is a view for describing a manufacturing method of the display device DSP.

FIG. 11 is a view for describing the manufacturing method of the display device DSP.

FIG. 12 is a view for describing the manufacturing method of the display device DSP.

FIG. 13 is a view for describing the manufacturing method of the display device DSP.

FIG. 14A is a view for describing the manufacturing method of the display device DSP.

FIG. 14B is a view for describing the manufacturing method of the display device DSP.

FIG. 15A is a view for describing the manufacturing method of the display device DSP.

FIG. 15B is a view for describing the manufacturing method of the display device DSP.

FIG. 16 is a view for describing the manufacturing method of the display device DSP.

FIG. 17 is a view for describing the manufacturing method of the display device DSP.

FIG. 18 is a view for describing the manufacturing method of the display device DSP.

FIG. 19 is a view for describing the manufacturing method of the display device DSP.

FIG. 20 is a view for describing the manufacturing method of the display device DSP.

FIG. 21 is a view for describing the manufacturing method of the display device DSP.

FIG. 22 is a view for describing the manufacturing method of the display device DSP.

### DETAILED DESCRIPTION

An object of the embodiment is to provide a display device capable of suppressing decreases in reliability and a manufacturing method of the same.

In general, according to one embodiment, a display device comprises a display panel comprising a display area comprising a plurality of display elements, a terminal area located outside the display area and comprising a plurality of terminals, and a strip-shaped area located between the display area and the terminal area, the display panel being folded around an axis in the strip-shaped area. The display panel comprises a resin substrate having flexibility, a first inorganic insulating layer not provided in the strip-shaped area but provided on the resin substrate between the display area and the strip-shaped area and between the strip-shaped area and the terminal area, a first organic insulating layer provided on the first inorganic insulating layer, and provided on the resin substrate in the strip-shaped area, a second organic insulating layer provided on the first organic insulating layer, and a plurality of first partitions provided above the second organic insulating layer. Each of the plurality of first partitions is formed in an overhang shape and extends along the axis.

According to another embodiment, a display device comprises a resin substrate having flexibility, a first inorganic insulating layer provided on the resin substrate, a first organic insulating layer provided on the first inorganic insulating layer, a second organic insulating layer provided on the first organic insulating layer, a second inorganic insulating layer provided on the second organic insulating layer, a display element including, in a display area, a lower electrode provided on the second organic insulating layer and having a peripheral portion covered with the second inorganic insulating layer, an organic layer provided on the lower electrode and having a light emitting layer, and an upper electrode provided on the organic layer, and a plurality of first partitions provided outside the display area. The first inorganic insulating layer constitutes a strip-shaped area from which the resin substrate is exposed. The first organic insulating layer contacts the resin substrate in the strip-shaped area. The plurality of first partitions are provided in the strip-shaped area. Each of the plurality of first partitions is formed in an overhang shape and extends along a long side of the strip-shaped area.

According to another embodiment, a manufacturing method of a display device comprises steps of forming a first inorganic insulating layer on a resin substrate, forming a strip-shaped area in which the first inorganic insulating layer is removed in a strip-shaped pattern, forming a first organic insulating layer on the first inorganic insulating layer and on the resin substrate in the strip-shaped area, forming a second organic insulating layer on the first organic insulating layer, forming a second inorganic insulating layer above the second organic insulating layer, and forming a plurality of first partitions on the second inorganic insulating layer in the strip-shaped area and forming a second partition on the second inorganic insulating layer in the display area. Each of the plurality of first partitions is formed in a straight-line shape extending along a long side of the strip-shaped area in plan view, and is formed in an overhang shape in cross-sectional view. The second partition is formed in a lattice shape surrounding the display element in plan view.

Embodiments can provide a display device capable of suppressing decreases in reliability and a manufacturing method of the same.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

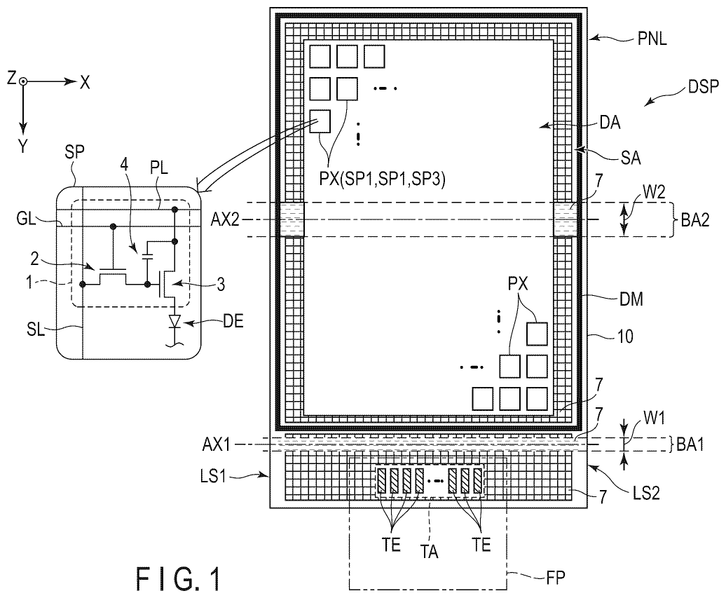

FIG. 1 is a plan view showing a configuration example of a display device DSP.

The display device DSP comprises a display panel PNL on an insulating substrate 10. The display panel PNL has a display area DA for displaying images and a surrounding area SA outside the display area DA. The substrate 10 is a resin substrate having flexibility.

In the illustrated example, the substrate 10 is formed in a rectangular shape in plan view and has a pair of long sides LS1 and LS2 extending in the second direction Y. The shape of the substrate 10 in plan view is not limited to the rectangular shape illustrated and may be another shape such as a square shape, a circular shape, or an elliptic shape.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are mutually different colors. Each pixel PX may include a subpixel SP, which displays another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to the scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to anode of the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The surrounding area SA comprises a terminal area TA, a dam portion DM, and a partition 7.

The display area DA and the terminal area TA are arranged in the second direction Y. For example, the terminal area TA comprises a plurality of terminals TE arranged in the first direction X. For example, each of the terminals TE extends in the second direction Y. For example, the plurality of terminals TE are electrically connected to a flexible printed circuit board FP as indicated by a chain double-dashed line. The plurality of terminals TE may be electrically connected to an IC chip.

The dam portion DM is formed in a frame shape surrounding the display area DA and is located between the display area DA and the terminal area TA. The dam portion DM is formed using an organic insulating layer provided on the display panel PNL and functions to suppress spreading of various resin layers applied to cover the display elements DE.

The partition 7 is provided between the display area DA and the dam portion DM and outside the dam portion DM. At least part of this partition 7 is formed of a conductive material. In plan view, the partition 7 can be formed in various shapes such as a lattice shape, a straight-line shape, a curved line shape, broken lines shape, and an island-like shape. Specific shapes of the partition 7 will be described later.

The display panel PNL has strip-shaped areas BA1 and BA2.

The strip-shaped area BA1 is located between the display area DA and the terminal area TA in the surrounding area SA and extends from the long side LS1 to the long side LS2. The strip-shaped area BA1 is an area foldable around an axis AX1 along the first direction X. The axis AX1 is parallel to the long sides of the strip-shaped area BA1.

The strip-shaped area BA2 is located in the surrounding area SA, intersects the display area DA, and extends from the long side LS1 to the long side LS2 along the first direction X. The strip-shaped area BA2 is an area foldable around an axis AX2 along the first direction X. In one example, a width W2 of the strip-shaped area BA2 in the second direction Y is greater than a width W1 of the strip-shaped area BA1 in the second direction Y.

The partition 7 provided in the strip-shaped area BA1 is formed in a straight-line shape extending along the axis AX1 or the long sides of the strip-shaped area BA1. The partitions 7 respectively provided between the long side LS1 and the display area DA and between the display area DA and the long side LS2 in the strip-shaped area BA2 are formed in a straight-line shape extending along the axis AX2. Of the strip-shaped area BA2, a partition 6 having a lattice shape is provided in the display area DA. This partition 6 will be described later in detail. The partition 7 provided in the surrounding area SA excluding the strip-shaped areas BA1 and BA2 are formed, for example, in a lattice shape and is electrically connected to the terminal TE that has a common potential among the plurality of terminals TE.

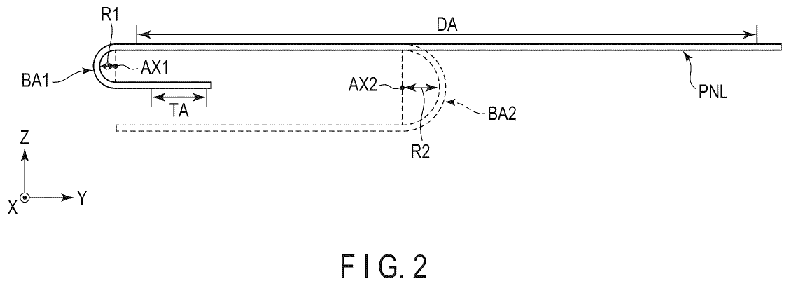

FIG. 2 is a view showing a state in which the display panel PNL shown in FIG. 1 is folded.

The display panel PNL is folded around the axis AX1 in the strip-shaped area BA1. The strip-shaped area BA1 is curved. In the display panel PNL, the terminal area TA opposite to the display area DA across the strip-shaped area BA1 is located on the back side of the display area DA. Fixing the display panel PNL in the state folded at the strip-shaped area BA1 can reduce a width along the second direction Y around the display area DA in the display device DSP, achieving a narrow-bezel design.

The display panel PNL is also foldable around the axis AX2 in the strip-shaped area BA2 as indicated by broken lines. A radius of curvature R2 of the strip-shaped area BA2 is greater than a radius of curvature R1 of the strip-shaped area BA1. The display area DA can display images in both in an extended state indicated by solid lines and in a folded state indicated by broken lines. Folding the display panel PNL at the strip-shaped area BA2 enables size reduction of the display device DSP.

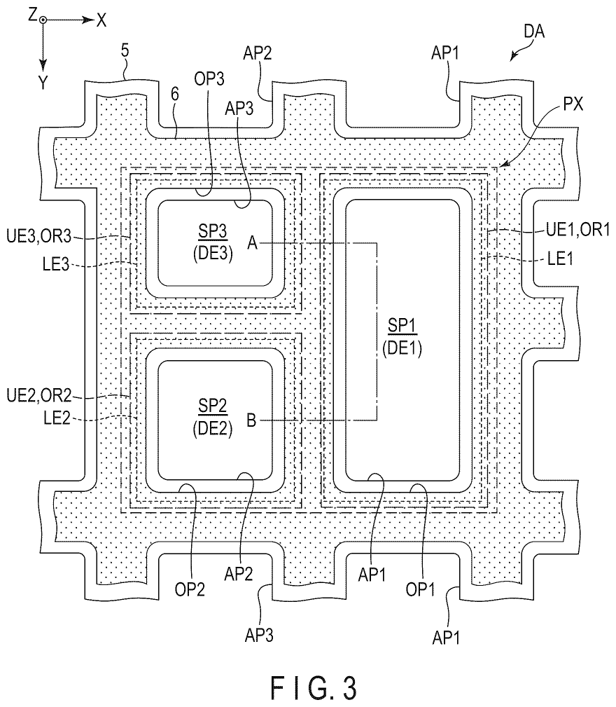

FIG. 3 is a view showing an example of the layout of the subpixels SP1, SP2, and SP3 in the display area DA.

In the illustrated example, the subpixels SP2 and SP3 are arranged in the second direction Y. Further, the subpixels SP1 and SP2 are arranged in the first direction X, and the subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An insulating layer 5 and the partition 6 are provided in the display area DA. The insulating layer 5 has apertures AP1, AP2, and AP3 in the respective subpixels SP1, SP2, and SP3. The insulating layer 5 having these apertures AP1, AP2, and AP3 may be called a rib.

The partition 6 overlaps the insulating layer 5 in plan view. The partition 6 is formed into a lattice shape surrounding the apertures AP1, AP2, and AP3. That is, the partition 6 has respective apertures OP1, OP2, and OP3 in the respective subpixels SP1, SP2, and SP3 in the same manner as the insulating layer 5. The aperture OP1 overlaps the aperture AP1. The aperture OP2 overlaps the aperture AP2. The aperture OP3 overlaps the aperture AP3. The partition 6 is conductive and electrically connected to the terminal TE having the common potential shown in FIG. 1.

The subpixels SP1, SP2, and SP3 comprise respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the insulating layer 5 in plan view.

In the illustrated example, the outlines of the lower electrodes LE1, LE2, and LE3 are indicated by broken lines, and the outlines of the organic layers OR1, OR2, and OR3 and the upper electrodes UE1, UE2, and UE3 are indicated by short dashed lines. The outlines of the respective lower electrodes, organic layers, and upper electrodes shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode, contact the partition 6, and are electrically connected to the partition 6.

In the illustrated example, the planar size of the aperture AP1, the planar size of the aperture AP2, and the planar size of the aperture AP3 differ from each other. The planar size of the aperture AP1 is greater than the aperture AP2. The planar size of the aperture AP2 is greater than the aperture AP3. The magnitude relationship of the planar sizes of the apertures AP1, AP2, and AP3 is not limited to the illustrated example.

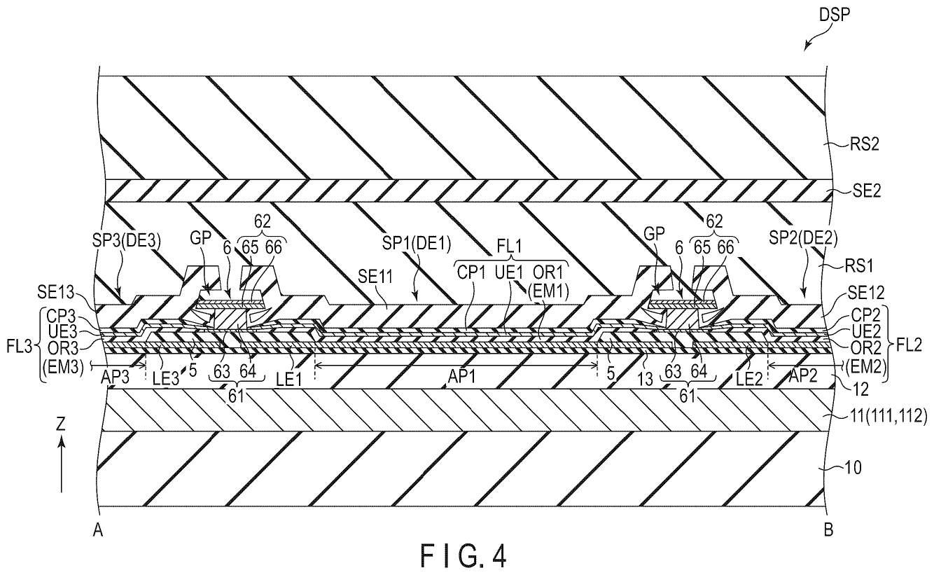

FIG. 4 is a schematic cross-sectional view of the display device DSP along the A-B line of FIG. 3.

A circuit layer 11 is provided on the substrate 10. The circuit layer 11 includes various circuits such as the pixel circuits 1 and various lines such as the scanning line GL, the signal line SL, and the power line PL shown in FIG. 1. The circuit layer 11 includes a plurality of insulating layers 111 and 112.

The inorganic insulating layer 111 is constituted by a plurality of inorganic insulating layers such as a barrier film for preventing moisture ingress through the substrate 10, a passivation film, and a gate insulating film. The insulating layer 112 is an organic insulating layer.

The insulating layer 12 is provided on the circuit layer 11. For example, the insulating layer 12 is an organic insulating layer that planarizes irregularities formed by the circuit layer 11.

An insulating layer 13 is an inorganic insulating layer provided on the insulating layer 12.

The lower electrodes LE1, LE2, and LE3 are provided on the insulating layer 13 and are spaced apart from each other. The insulating layer 5 is an inorganic insulating layer and is provided on the insulating layer 13 and the lower electrodes LE1, LE2, and LE3. The aperture AP1 of the insulating layer 5 overlaps the lower electrode LE1. The aperture AP2 of the insulating layer 5 overlaps the lower electrode LE2. The aperture AP3 of the insulating layer 5 overlaps the lower electrode LE3. The lower electrodes LE1, LE2, and LE3 are connected to the pixel circuits 1 of the respective subpixels SP1, SP2, and SP3.

The partition 6 is formed in an overhang shape and comprises a lower portion 61 having conductivity and provided on the insulating layer 5 and an upper portion 62 provided on the lower portion 61.

In the illustrated example, the lower portion 61 comprises a bottom layer 63 provided on the insulating layer 5 and a stem layer 64 provided between the bottom layer 63 and the upper portion 62. The bottom layer 63 is thinner than the stem layer 64. The bottom layer 63 has the width greater than the stem layer 64. Both end portions of the bottom layer 63 protrude relative to the side surfaces of the stem layer 64.

The upper portion 62 comprises a top layer 65 provided on the stem layer 64 and a cover layer 66 provided on the top layer 65. The top layer 65 and the cover layer 66 have widths greater than the stem layer 64. Both end portions of each of the top layer 65 and the cover layer 66 protrude relative to the side surfaces of the stem layer 64. In the present specification, the side surfaces of the stem layer 64 are assumed to be the side surfaces of the stem layer 64 that extend between the bottom layer 63 and the top layer 65. In the illustrated example, the upper portion 62 has the width greater than the bottom layer 63. The bottom layer 63 may have a width greater than the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In the present specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 includes a cap layer CP1 and a sealing layer SE11, the subpixel SP2 includes a cap layer CP2 and a sealing layer SE12, and the subpixel SP3 includes a cap layer CP3 and a sealing layer SE13. The cap layers CP1, CP2, and CP3 function as optical adjustment layers, which improve the extraction efficiency of light emitted from the respective organic layers OR1, OR2, and OR3. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

Each of the sealing layers SE11, SE12, and SE13 extends above the partition 6. The edge portion of each of the sealing layers SE11, SE12, and SE13 is located above the partition 6.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

None of the stacked films FL1, FL2, and FL3 are provided on the partition 6. Gaps GP are formed between the sealing layer SE11 and the partition 6, between the sealing layer SE12 and the partition 6, and between the sealing layer SE13 and the partition 6.

A transparent resin layer RS1 covers the partition 6 and the sealing layers SE11, SE12, and SE13. The resin layer RS1 fills each of the gaps GP respectively formed between the sealing layer SE11 and the partition 6, between the sealing layer SE12 and the partition 6, and between the sealing layer SE13 and the partition 6.

The sealing layer SE2 covers the resin layer RS1. A transparent resin layer RS2 is provided on the sealing layer SE2.

For example, the substrate 10 is formed of an organic insulating material such as a polyimide.

Each of the insulating layers 111 and 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the insulating layer 5 is formed of a silicon oxynitride, and each of the sealing layers SE11, SE12, SE13, and SE2 is formed of a silicon nitride.

The insulating layers 13 interposed between the insulating layer 12 and the lower electrodes LE1, LE2, and LE3 and between the insulating layer 12 and the insulating layer 5 are formed of materials different from the insulating layer 5. For example, the insulating layer 13 is formed of a silicon nitride. This insulating layer 13 functions as a water-proof layer blocking water infiltration to the display elements DE1, DE2, and DE3 through the insulating layer 12.

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. Alternately, the bottom layer 63 may be formed of an alloy of molybdenum and tungsten (MoW). The stem layer 64 is formed of a material different from the bottom layer 63 and the top layer 65, and is formed of, for example, an aluminum-based material such as aluminum or an aluminum compound.

The upper portion 62 of the partition 6 is formed of, for example, a conductive material. However, the upper portion 62 may be formed of an insulating material. In the illustrated example, the top layer 65 and the cover layer 66 of the upper portion 62 are both formed of conductive materials. The top layer 65 is formed of, for example, a titanium-based material such as titanium or a titanium compound. The cover layer 66 is formed of a material different from the top layer 65 and for example, formed of an oxide conductive material such as an ITO.

For example, each of the lower electrodes LE1, LE2, and LE3 is a multilayer body including an oxide conductive layer and a metal layer. The oxide conductive layer is formed of an oxide conductive material such as an ITO. The metal layer is formed of a metal material such as silver and functions as a reflective layer. For example, each of the lower electrodes LE1, LE2, and LE3 is a multilayer body including a metal layer between a pair of oxide conductive layers.

The organic layer OR1 includes a light emitting layer EM1. The organic layer OR2 includes a light emitting layer EM2. The organic layer OR3 includes a light emitting layer EM3. The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. The light emitting layer EM1 may be formed of a material that emits light in the green wavelength. The light emitting layer EM2 may be formed of a material that emits light in the blue wavelength.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The illustrated circuit layer 11 and insulating layers 12, 13, and 5 are provided across the display area DA and the surrounding area SA.

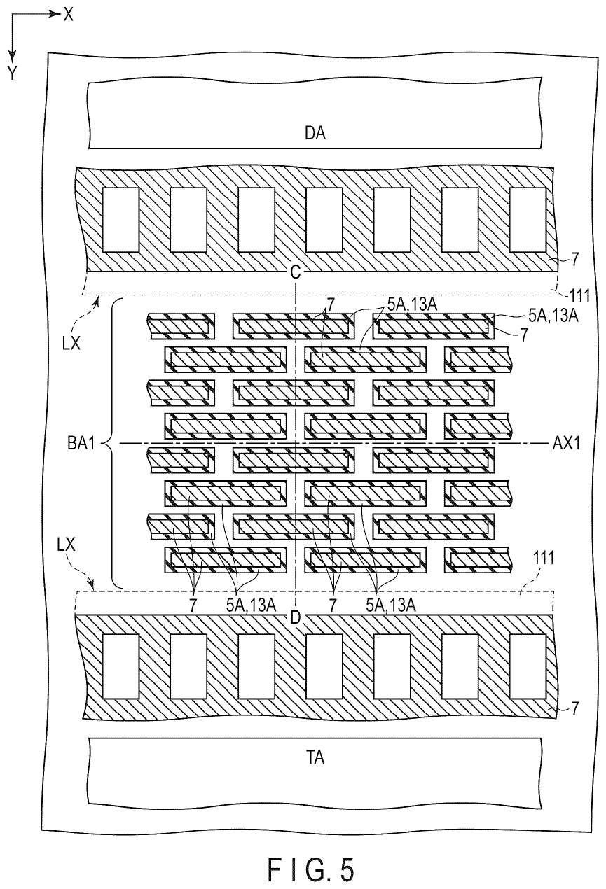

FIG. 5 is a plan view showing a shape of the partition 7 in the strip-shaped area BA1.

In the illustrated example, the strip-shaped area BA1 corresponds to an area where the insulating layer 111 indicated by broken lines is missing in a strip pattern. The strip-shaped area BA1 has the pair of long sides LX extending in the first direction X. The long side LX corresponds to the edge portion of the insulating layer 111. The long side LX is parallel to the axis AX1.

The plurality of partitions 7 provided in the strip-shaped area BA1 each extend along the long sides LX (or the axis AX1) and are formed in a straight-line shape. The plurality of partitions 7 are arranged along the long sides LX and are arranged in a direction orthogonal to the long sides LX (or in the second direction Y). In the illustrated example, the plurality of partitions 7 are arranged in a staggered pattern in the strip-shaped area BA1.

In the display area DA shown in FIG. 3, the insulating layer 5 is formed in a lattice shape. In contrast, in the strip-shaped area BA1, the insulating layer 5 includes a plurality of island-like portions 5A. For example, each of the plurality of island-like portions 5A is formed in a rectangular shape extending longer in the first direction X. One partition 7 overlaps one island-like portion 5A. The insulating layer 13 includes an island-like portion 13A overlapping the island-like portion 5A. The island-like portion 13A has substantially the same shape as the island-like portion 5A in plan view.

The partition 7 overlaps the insulating layer 111 and is formed in a lattice shape outside the strip-shaped area BA1.

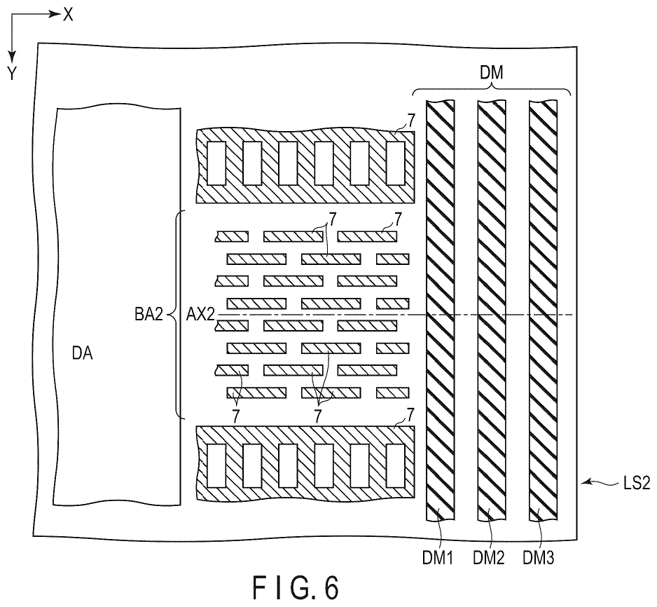

FIG. 6 is a plan view showing a shape of the partition 7 in the strip-shaped area BA2.

Here, an area located between the display area DA and the long side LS2 in the strip-shaped area BA2 is shown in an enlarged manner. For example, the dam portion DM comprise three dams DM1, DM2, and DM3. The number of the dams in the dam portion DM is not limited to the illustrated example.

The plurality of partitions 7 arranged in the strip-shaped area BA2 each extend along the axis AX2 and are formed in a straight-line shape. The plurality of partitions 7 are arranged along the axis AX2 and are arranged in a direction orthogonal to the axis AX2. In the illustrated example, the plurality of partitions 7 are arranged in a staggered pattern in the strip-shaped area BA2.

The partition 7 is formed in a lattice shape outside the strip-shaped area BA2.

In the illustrated example, the partition 7 is not provided between the dam portion DM and the long side LS2. Alternatively, the partition 7 having a straight-line shape or the partition 7 having a lattice shape may be provided between these portions.

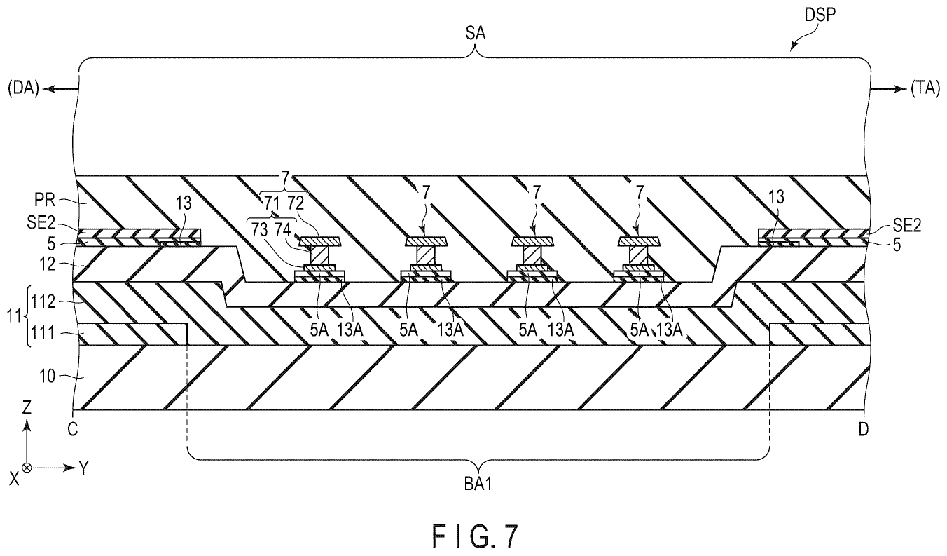

FIG. 7 is a schematic cross-sectional view of the display device DSP along the C-D line of FIG. 5.

In the surrounding area SA of the display device DSP, the insulating layer 111 is provided on the substrate 10 between the display area DA and the strip-shaped area BA1 and between the strip-shaped area BA1 and the terminal area TA. That is, the insulating layer 111 forms the strip-shaped area BA1 that exposes the substrate 10.

The insulating layer 112 is provided on the insulating layer 111 and is provided on the substrate 10 in the strip-shaped area BA1 to contact the substrate 10. The insulating layer 12 is provided on the insulating layer 112.

The plurality of partitions 7 are provided above the insulating layer 12 in the strip-shaped area BA1. Each of the plurality of partitions 7 has an overhang shape in cross-sectional view as described above. That is, the partition 7 comprises a lower portion 71 and an upper portion 72 provided on the lower portion 71. The lower portion 71 comprises a bottom layer 73 and a stem layer 74 provided on the bottom layer 73. The upper portion 72 is provided on the stem layer 74. Though not shown in details, the upper portion 72 comprises a top layer and a cover layer in the same manner as the upper portion 62 of the partition 6 shown in FIG. 4. Both end portions of the bottom layer 73 and both end portions of the upper portion 72 protrude relative to the side surfaces of the stem layer 74.

These partitions 7 can be formed in the same process using the same materials as the partition 6 in the display area DA. In the lower portion 71, the bottom layer 73 is formed of the same conductive material as the bottom layer 63, and the stem layer 74 is formed of the same conductive material as the stem layer 64. The upper portion 72 is also formed of the same material as the upper portion 62.

The insulating layer 5 is provided on the insulating layer 12 outside the strip-shaped area BA1. The island-like portion 5A provided in the strip-shaped area BA1 of the insulating layer 5 is interposed between the partition 7 and the insulating layer 12. The bottom layer 73 of the partition 7 is provided on the island-like portion 5A.

The insulating layer 13 is interposed in part between the insulating layers 12 and 5 outside the strip-shaped area BA1. The insulating layer 5 contacts the insulating layer 12 outside the insulating layer 13. The island-like portion 13A provided in the strip-shaped area BA1 of the insulating layer 13 is interposed between the island-like portion 5A and the insulating layer 12.

The sealing layer SE2 is not provided in the strip-shaped area BA1 but is provided on the insulating layer 5 outside the strip-shaped area BA1. The sealing layers SE11, SE12, and SE13 and the resin layers RS1 and RS2 provided in the display area DA are not provided in the strip-shaped area BA1.

A protective resin layer PR is provided at least in the strip-shaped area BA1 and covers the plurality of partitions 7. The protective resin layer PR covers the island-like portions 5A and 13A and contacts the insulating layer 12 exposed from the island-like portions 5A and 13A. In the illustrated example, the protective resin layer PR extends to an area outside the strip-shaped area BA1, i.e., an area overlapping the insulating layer 111 and is provided on the sealing layer SE2.

In this manner, in the strip-shaped area BA1, the partitions 7 extend along the axis AX1 of the strip-shaped area BA1. Thus, when the display panel PNL is folded in the strip-shaped area BA1, breakage of the partitions 7 and stripping of the partitions 7 are suppressed.

In the strip-shaped area BA1, no inorganic insulating layer continuously extends across the display area DA and the terminal area TA. Only the island-like portions 5A and 13A divided into a plurality of island-like portions are provided as inorganic insulating layers. The island-like portions 5A and 13A extend along the axis AX1 of the strip-shaped area BA1. As illustrated, the insulating layers 112 and 12, which are organic layers, and the protective resin layer PR are provided on the resin substrate 10. Thus, when the display panel PNL is folded in the strip-shaped area BA1, breakage of the island-like portions 5A and 13A is suppressed, and defects such as stripping of other components associated with breakage of inorganic insulating layers are suppressed. Thus, a decrease in reliability is suppressed.

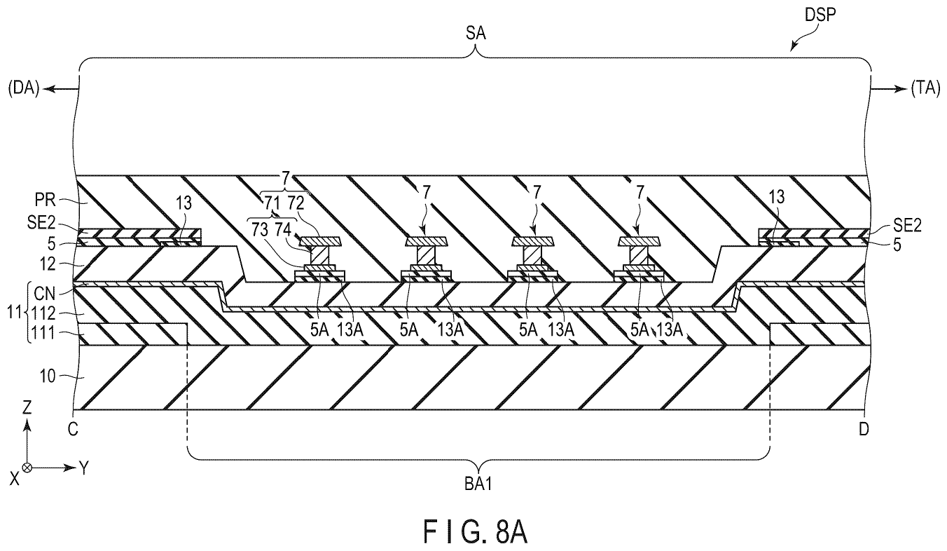

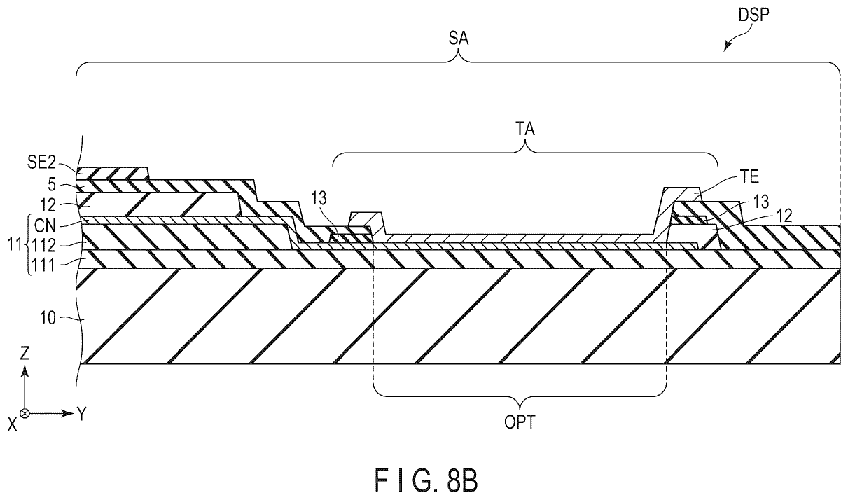

FIG. 8A is a schematic cross-sectional view of the display device DSP along a connection line CN in the strip-shaped area BA1 shown in FIG. 5.

That is, the circuit layer 11 comprises the connection line CN provided across the display area DA and the terminal area TA. For example, the connection line CN is a line for electrically connecting various wirings that supply signals necessary to drive the display elements DE to the terminals TE. The connection line CN is formed, for example, as a multilayer body having an aluminum layer between a pair of titanium layers or a multilayer body having an aluminum layer between a pair of molybdenum layers. In the strip-shaped area BA1, the connection line CN is provided on the insulating layer 112 and is covered with the insulating layer 12.

In this manner, in the strip-shaped area BA1, the connection line CN is interposed between the insulating layer 112 and the insulating layer 12, which are organic insulating layers more flexible than inorganic insulating layers. Thus, when the display panel PNL is folded in the strip-shaped area BA1, breakage of the connection line CN is suppressed.

FIG. 8B is a schematic cross-sectional view of the display device DSP including the terminal area TA.

In the terminal area TA, the insulating layer 111 is provided on the substrate 10. The insulating layer 112 is not provided in the terminal area TA and exposes the insulating layer 111. The connection line CN is provided on the insulating layer 111. The insulating layer 12 exposes the connection line CN and covers the end of the connection line CN. The insulating layers 13 and 5 have apertures OPT exposing the connection line CN. The terminal TE is formed in an island-like shape and contacts the connection line CN in the aperture OPT. The peripheral portion of the terminal TE is located on the insulating layer 5.

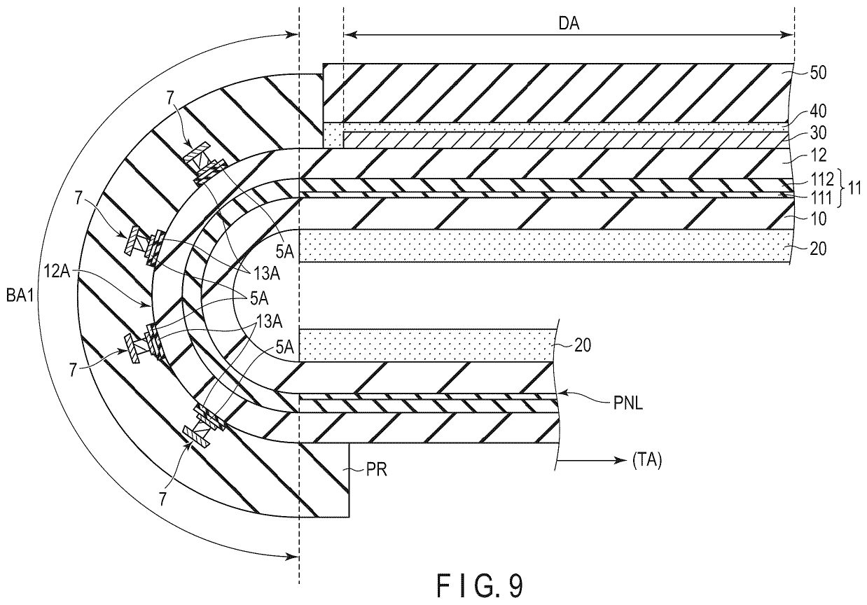

FIG. 9 is an enlarged cross-sectional view of the display panel PNL folded in the strip-shaped area BA1.

A support body 20 is bonded to the substrate 10. The substrate 10 is located between the support body 20 and the circuit layer 11. The support body 20 is not provided in the strip-shaped area BA1 and exposes the substrate 10. This support body 20 has a rigidity higher than the substrate 10, is provided in the display area DA, and maintains the flatness of the display area DA. Further, the support body 20 is provided in the terminal area TA (not shown) and maintains the flatness of the terminal area TA. Though not described in detail, the support body 20 is preferably not provided in the strip-shaped area BA2 either.

A display portion 30 includes the insulating layer 13 provided on the insulating layer 12, the insulating layer 5, the partition 6, and the display elements DE1, DE2, and DE3. A sealing portion 40 is provided to cover the display portion 30 and includes the sealing layers SE11, SE12, and SE13, the resin layer RS1, the sealing layer SE2, and the resin layer RS2. An optical film 50 is provided on the sealing portion 40 in the display area DA. The optical film 50 is, for example, a circular polarizer.

The insulating layer 12 is folded in the strip-shaped area BA1 to form a curved surface 12A on its surface. The curved surface 12A is formed in an arcuate shape in cross-sectional view. The plurality of partitions 7 provided in the strip-shaped area BA1 are formed on the curved surface 12A of the insulating layer 12. The protective resin layer PR covers the plurality of partitions 7 in the strip-shaped area BA1. One end of the protective resin layer PR contacts the sealing portion 40 and the optical film 50.

The following will describe an example of the manufacturing method of the display device DSP.

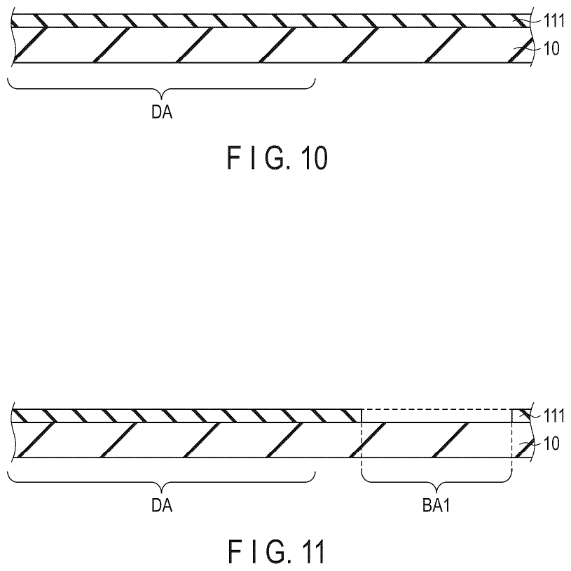

First, as shown in FIG. 10, a plurality of inorganic insulating materials are stacked on the substantially entire surface of the substrate 10 formed of a resin to form the inorganic insulating layer 111. Support substrates such as a glass substrate are provided below the substrate 10. The illustration of these support substrates is omitted. The detailed description on the formation steps of the circuit layer 11 is omitted as well.

Next, as shown in FIG. 11, the insulating layer 111 is removed in a strip pattern outside the display area DA to form the strip-shaped area BA1. The substrate 10 is made exposed in the strip-shaped area BA1.

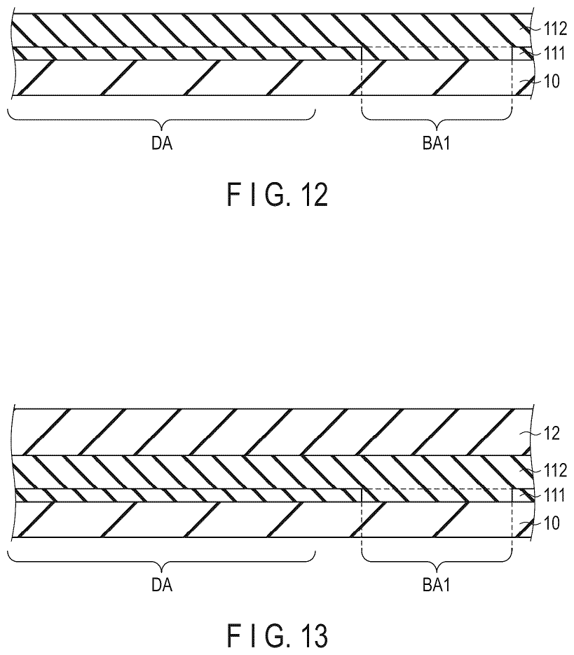

Next, as shown in FIG. 12, the insulating layer 112 is formed on the insulating layer 111 and the substrate 10 in the strip-shaped area BA1.

Next, as shown in FIG. 13, the insulating layer 12 is formed on the insulating layer 112.

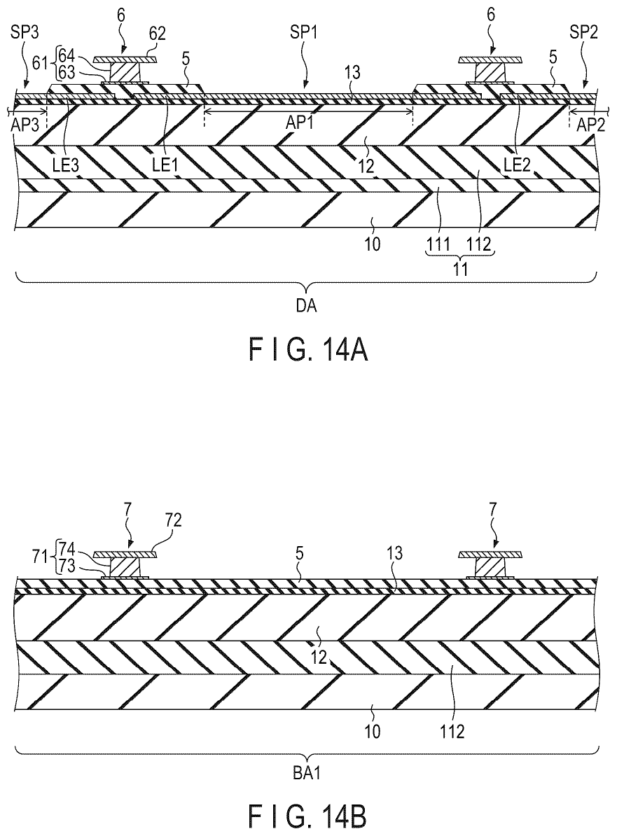

Next, as shown in FIG. 14A, in the display area DA, the lower electrode LE1 of the subpixel SP1, the lower electrode LE2 of the subpixel SP2, and the lower electrode LE3 of the subpixel SP3 are formed on the insulating layer 13, after the formation of the insulating layer 13 on the insulating layer 12. Then, after the formation of the insulating layer 5, the partition 6 having the lower portion 61 located on the insulating layer 5 and the upper portion 62 located on the lower portion 61 is formed on the insulating layer 5. The insulating layer 5 has the apertures AP1, AP2, and AP3 overlapping the lower electrodes LE1, LE2, and LE3, respectively. The partition 6 may be formed after the formation of the insulating layer 5 having the apertures AP1, AP2, and AP3. Alternatively, the apertures AP1, AP2, and AP3 may be formed in the insulating layer 5 after the formation of the partition 6. The partition 6 obtained in this manner is formed to have an overhang shape in cross section as illustrated and also is formed in a lattice shape in plan view as shown in FIG. 3.

In contrast, as shown in FIG. 14B, in the strip-shaped area BA1, the plurality of partitions 7 are formed on the insulating layer 5 after the formation of the insulating layers 13 and 5 on the insulating layer 12. The partition 7 has the lower portion 71 located on the insulating layer 5 and the upper portion 72 located on the lower portion 71. The lower portion 71 is formed simultaneously with the lower portion 61. The upper portion 72 is formed simultaneously with the upper portion 62. The plurality of partitions 7 obtained in this manner are formed to have an overhang shape in cross section as illustrated and also are formed in a straight-line shape extending along the long side LX of the strip-shaped area BA1 in plan view as shown in FIG. 5.

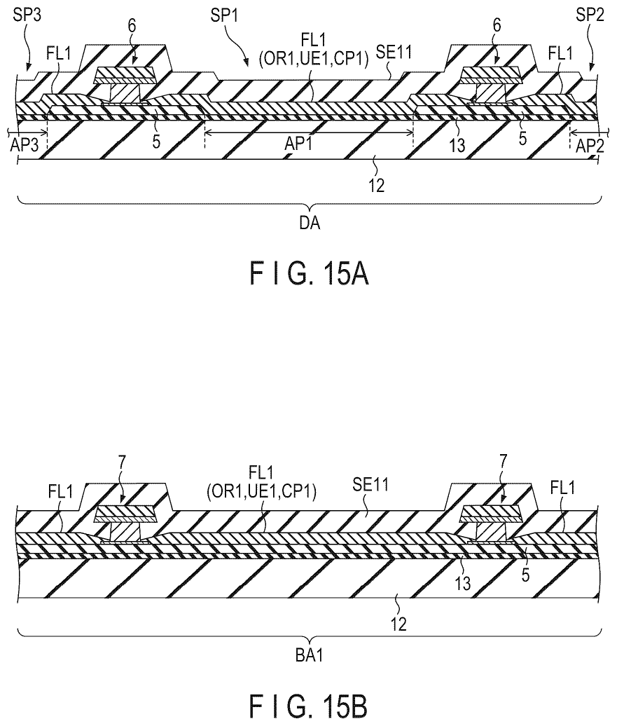

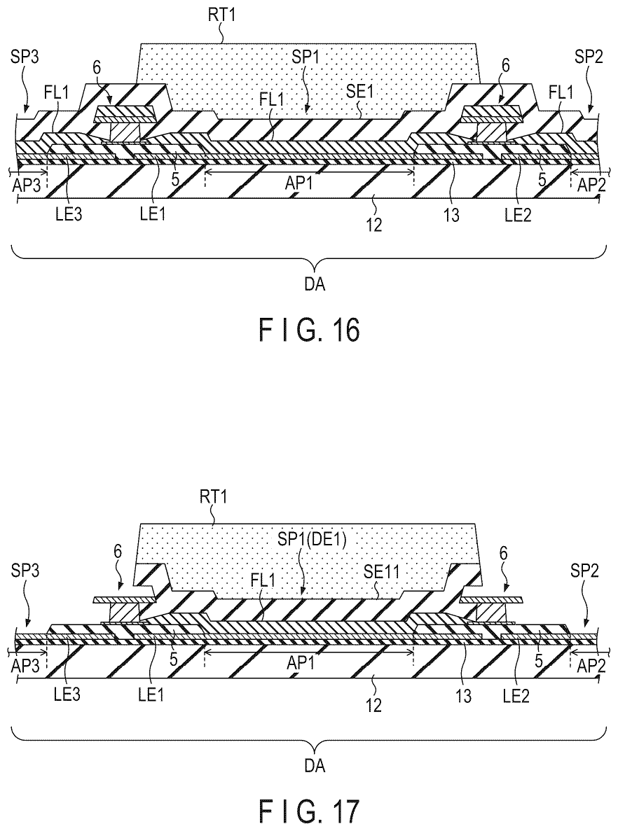

Next, the display element DE1 is formed in the display area DA. FIG. 15A, FIG. 15B, and FIG. 16 to FIG. 22 omit the illustration of components located below the insulating layer 12.

First, as shown in FIG. 15A, the stacked film FL1 is formed in the display area DA. The stacked film FL1 includes the organic layer OR1 contacting the lower electrode LE1 through the aperture AP1, the upper electrode UE1 covering the organic layer OR1 and contacting the lower portion 61 of the partition 6, and the cap layer CP1 located on the upper electrode UE1. The organic layer OR1 includes a hole injection layer, a hole transport layer, an electron blocking layer, the light emitting layer EM1, a hole blocking layer, an electron transport layer, an electron injection layer, and the like. Each of the organic layer OR1, the upper electrode UE1, and the cap layer CP1 is formed by vapor deposition using the partition 6 as a mask. The partition 6 having an overhang shape divides the stacked film FL1 into a plurality of parts. These organic layer OR1, the upper electrode UE1, and the cap layer CP1 are continuously formed in a state while maintaining a vacuum environment.

Subsequently, the sealing layer SE11 is formed on the stacked film FL1. The sealing layer SE11 is formed by stacking inorganic insulating materials (for example, a silicon nitride) in a Chemical Vapor Deposition (CVD) device. The sealing layer SE11 continuously covers these parts, into which the stacked film FL1 has been divided, and the partition 6.

As shown in FIG. 15B, the stacked film FL1 is also formed in the strip-shaped area BA1 at the same time as forming the stacked film FL1 in the display area DA. The stacked film FL1 includes the organic layer OR1, the upper electrode UE1, and the cap layer CP1 and is formed on the insulating layer 5. The stacked film FL1 is formed by vapor deposition using the partition 7 as a mask. In the strip-shaped area BA1 as well, the partition 7 having an overhang shape divides the stacked film FL1 into a plurality of parts.

The sealing layer SE11 is also formed in the strip-shaped area BA1 at the same time as forming the sealing layer SE11 in the display area DA. The sealing layer SE11 continuously covers these parts, into which the stacked film FL1 has been divided, and the partition 7.

Next, as shown in FIG. 16, a resist RT1 patterned into a predetermined shape is formed on the sealing layer SE11 in the display area DA. The resist RT1 overlaps the subpixel SP1 and part of the partition 6 around the subpixel SP1. In the strip-shaped area BA1, the resist RT1 is not provided, and the sealing layer SE11 is made exposed as shown in FIG. 15B.

Next, as shown in FIG. 17, the sealing layer SE11 and the stacked film FL1 are patterned using the resist RT1 as a mask. Thus, the sealing layer SE11 and the stacked film FL1 exposed from the resist RT1 are removed. This etching sequentially removes the sealing layer SE11 exposed from the resist RT1, the cap layer CP1 exposed from the sealing layer SE11, the upper electrode UE1 exposed from the cap layer CP1, and the organic layer OR1 exposed from the upper electrode UE1. Thus, the lower electrode LE2 of the subpixel SP2 and the lower electrode LE3 of the subpixel SP3 are made exposed.

Then, the resist RT1 is removed. Thus, the display element DE1 is formed in the subpixel SP1.

In the patterning using the resist RT1 as a mask, the stacked film FL1 and the sealing layer SE11 in the strip-shaped area BA1 shown in FIG. 15B are both removed. A cross section of the strip-shaped area BA1 from which the stacked film FL1 and the sealing layer SE11 have been removed is the same as the cross section shown in FIG. 14B.

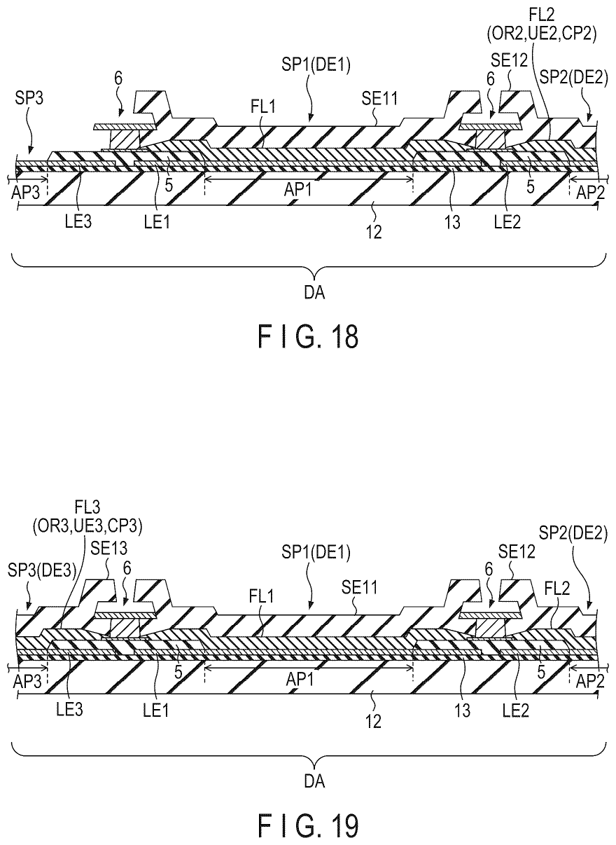

Next, as shown in FIG. 18, the display element DE2 is formed. The procedure of forming the display element DE2 is the same as that of forming the display element DE1. That is, the organic layer OR2 including the light-emitting layer EM2, the upper electrode UE2, and the cap layer CP2 are formed in this order on the lower electrode LE2 to form the stacked film FL2. Subsequently, the sealing layer SE12 is formed on the stacked film FL2. Thereafter, a resist is formed on the sealing layer SE12, and the etching using this resist as a mask patterns the sealing layer SE12, the cap layer CP2, the upper electrode UE2, and the organic layer OR2. The resist is removed after this patterning. Thus, the display element DE2 is formed in the subpixel SP2, and the lower electrode LE3 of the subpixel SP3 is exposed.

Next, as shown in FIG. 19, the display element DE3 is formed. The procedure of forming the display element DE3 is the same as that of forming the display element DE1. That is, the organic layer OR3 including the light-emitting layer EM3, the upper electrode UE3, and the cap layer CP3 are formed in this order on the lower electrode LE3 to form the stacked film FL3. Subsequently, the sealing layer SE13 is formed on the stacked film FL3. Thereafter, a resist is formed on the sealing layer SE13, and the etching using this resist as a mask patterns the sealing layer SE13, the cap layer CP3, the upper electrode UE3, and the organic layer OR3. The resist is removed after this patterning. Thus, the display element DE3 is formed in the subpixel SP3.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

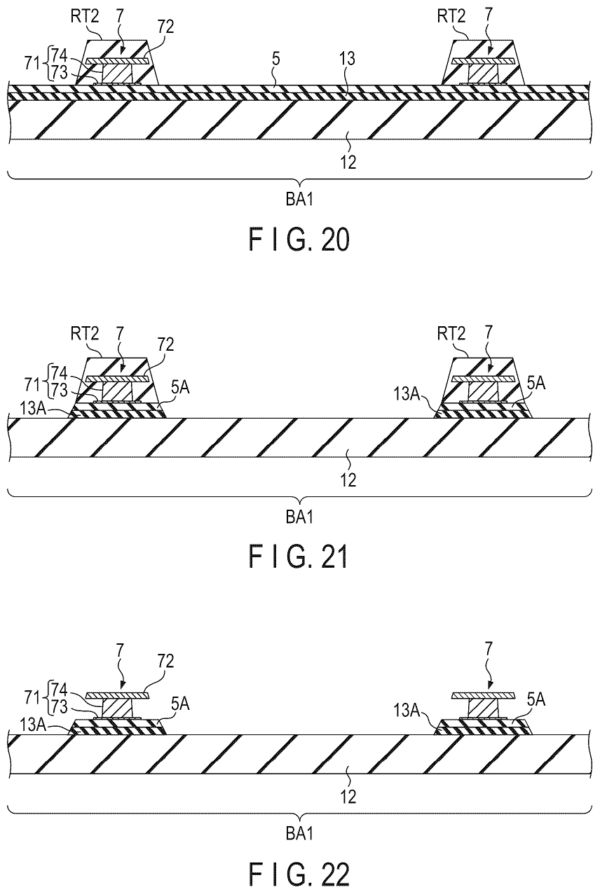

As shown in FIG. 20, after the formation of the display elements DE1, DE2, and DE3, a resist RT2 individually covering each of the plurality of partitions 7 is formed in the strip-shaped area BA1. The insulating layer 5 is made exposed between adjacent resists RT2.

Next, as shown in FIG. 21, the insulating layers 5 and 13 are patterned using the resist RT2 as a mask. Thus, the insulating layers 5 and 13 exposed from the resist RT2 are sequentially removed. This patterning divides the insulating layer 5 into the plurality of island-like portions 5A and divides the insulating layer 13 into the plurality of island-like portions 13A. The insulating layer 12 is made exposed between the island-like portions 5A and 13A adjacent to each other.

Then, the resist RT2 is removed as shown in FIG. 22.

The step of forming the island-like portions 5A may be performed simultaneously with the step of forming the apertures AP1, AP2, and AP3 described with reference to FIG. 14A.

Thereafter, the resin layer RS1, the sealing layer SE2, and the resin layer RS2 shown in FIG. 4 and the like are formed. Thus, the display device DSP is completed.

In the manufacturing method described above, the stacked film FL1 formed in the strip-shaped area BA1 is subdivided by the partitions 7. Compared with a case where the stacked film FL1 is not subdivided, the area of a continuous stacked film FL1 is reduced. Thus, stress applied to the stacked film FL1 is dispersed. Further, the stacked film FL1 is constrained by the partitions 7 and the sealing layer SE11. Thus, stripping of the stacked film FL1 is suppressed.

When the stacked films FL2 and FL3 are formed in the strip-shaped area BA1, these stacked films FL2 and FL3 are similarly subdivided by the partitions 7. Thus, the stripping of these stacked films FL2 and FL3 are suppressed.

Furthermore, the configuration in which the insulating layer 13 is interposed between the insulating layers 12 and 5 can suppress undesired removal of the insulating layer 12 during the patterning of the insulating layer 5.

In the above embodiments, for example, the insulating layer 111 corresponds to the first inorganic insulating layer, the insulating layer 5 corresponds to the second inorganic insulating layer, and the insulating layer 13 corresponds to the third inorganic insulating layer. The insulating layer 112 corresponds to the first organic insulating layer, and the insulating layer 12 corresponds to the second organic insulating layer. The partition 7 corresponds to the first partition, and the partition 6 corresponds to the second partition.

As explained above, the present embodiment can provide a display device capable of suppressing decreases in reliability and a manufacturing method of the same.

All of the display devices and the manufacturing methods of the same that can be implemented by a person of ordinary skill in the art through arbitrary design changes to the display devices and the manufacturing methods of the same described above as the embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long

as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a display panel comprising:
a display area comprising a plurality of display elements;
a terminal area located outside the display area and comprising a plurality of terminals; and
a strip-shaped area located between the display area and the terminal area, the display panel being folded around an axis in the strip-shaped area, wherein
the display panel comprises:
a resin substrate having flexibility;
a first inorganic insulating layer not provided in the strip-shaped area but provided on the resin substrate between the display area and the strip-shaped area and between the strip-shaped area and the terminal area;
a first organic insulating layer provided on the first inorganic insulating layer, and provided on the resin substrate in the strip-shaped area;
a second organic insulating layer provided on the first organic insulating layer; and
a plurality of first partitions provided above the second organic insulating layer, and
each of the plurality of first partitions is formed in an overhang shape and extends along the axis.

2. The display device of claim 1, wherein
the plurality of first partitions are arranged on a curved surface of the second organic insulating layer.

3. The display device of claim 1, further comprising:
a second inorganic insulating layer provided on the second organic insulating layer, wherein
the second inorganic insulating layer includes a plurality of island-like portions in the strip-shaped area, and
each of the plurality of island-like portions is interposed between one of the plurality of first partitions and the second organic insulating layer.

4. The display device of claim 3, wherein
each of the plurality of first partitions comprises a bottom layer provided on the island-like portion, a stem layer provided on the bottom layer, and an upper portion provided on the stem layer, and
both end portions of the bottom layer and both end portions of the upper portion protrude relative to a side surface of the stem layer.

5. The display device of claim 3, further comprising:
a third inorganic insulating layer interposed between the second organic insulating layer and the second inorganic insulating layer outside the strip-shaped area and formed of a material different from the second inorganic insulating layer.

6. The display device of claim 1, further comprising:
a protective resin layer covering the plurality of first partitions in the strip-shaped area and contacting the second organic insulating layer.

7. The display device of claim 1, further comprising:
a connection line provided across the display area and the terminal area, wherein
the connection line is provided on the first organic insulating layer and covered with the second organic insulating layer in the strip-shaped area.

8. The display device of claim 1, further comprising:
a second partition surrounding each of the plurality of display elements in the display area and formed in an overhang shape, wherein
each of the first partition and the second partition includes a lower portion and an upper portion provided on the lower portion, and
the lower portions of the first partition and the second partition are formed of same conductive material.

9. The display device of claim 8, wherein
each of the plurality of display elements comprises:
a lower electrode;
an organic layer provided on the lower electrode and including a light emitting layer; and
an upper electrode provided on the organic layer and contacting the lower portion of the second partition.

10. The display device of claim 9, further comprising:
a cap layer provided on the upper electrode; and
a sealing layer formed of an inorganic insulating material and covering the cap layer and the second partition, wherein
the sealing layer is not provided in the strip-shaped area.

11. A display device comprising:
a resin substrate having flexibility;
a first inorganic insulating layer provided on the resin substrate;
a first organic insulating layer provided on the first inorganic insulating layer;
a second organic insulating layer provided on the first organic insulating layer;
a second inorganic insulating layer provided on the second organic insulating layer;
a display element including, in a display area,
a lower electrode provided on the second organic insulating layer and having a peripheral portion covered with the second inorganic insulating layer,
an organic layer provided on the lower electrode and having a light emitting layer, and
an upper electrode provided on the organic layer; and
a plurality of first partitions provided outside the display area, wherein
the first inorganic insulating layer defines a strip-shaped area exposing the resin substrate,
the first organic insulating layer contacts the resin substrate in the strip-shaped area,
the plurality of first partitions are provided in the strip-shaped area, and
each of the plurality of first partitions is formed in an overhang shape and extends along a long side of the strip-shaped area.

12. The display device of claim 11, wherein
the plurality of first partitions are arranged along the long side in plan view.

13. The display device of claim 11, wherein
the plurality of first partitions are arranged in a direction orthogonal to the long side in plan view.

14. The display device of claim 11, wherein
the plurality of first partitions are arranged in a staggered pattern in the strip-shaped area in plan view.

15. The display device of claim 11, wherein
the second inorganic insulating layer includes a plurality of island-like portions in the strip-shaped area, and
each of the plurality of island-like portions is interposed between one of the plurality of first partitions and the second organic insulating layer.

16. The display device of claim 11, further comprising:
a third inorganic insulating layer interposed between the second organic insulating layer and the second inorganic insulating layer in the display area and formed of a material different from the second inorganic insulating layer, wherein
the third inorganic insulating layer exposes the second organic insulating layer in the strip-shaped area.

17. A manufacturing method of a display device, the method comprising steps of:
forming a first inorganic insulating layer on a resin substrate;
forming a strip-shaped area in which the first inorganic insulating layer is removed in a strip-shaped pattern;
forming a first organic insulating layer on the first inorganic insulating layer and on the resin substrate in the strip-shaped area;
forming a second organic insulating layer on the first organic insulating layer;
forming a second inorganic insulating layer above the second organic insulating layer; and
forming a plurality of first partitions on the second inorganic insulating layer in the strip-shaped area and forming a second partition on the second inorganic insulating layer in the display area, wherein
each of the plurality of first partitions is formed in a straight-line shape extending along a long side of the strip-shaped area in plan view, and is formed in an overhang shape in cross-sectional view, and
the second partition is formed in a lattice shape surrounding a display element in plan view.

18. The manufacturing method of claim 17, further comprising steps of:
forming a resist separately covering the plurality of first partitions; and
removing the second inorganic insulating layer exposed from the resist.

19. The manufacturing method of claim 17, further comprising steps of:
forming a lower electrode of the display element on the second organic insulating layer in the display area; and
forming a stacked film including an organic layer including a light emitting layer, an upper electrode, and a cap layer, on the lower electrode, after forming the first partition and the second partition, wherein
the stacked film is divided by the first partition in the strip-shaped area.

20. The manufacturing method of claim 19, further comprising steps of:
forming a sealing layer covering the stacked film by stacking an inorganic insulating material;
forming a resist patterned into a predetermined shape on the sealing layer; and
patterning the sealing layer and the stacked film using the resist as a mask, wherein
the sealing layer and the stacked film are removed in the strip-shaped area.
